(19) United States
(12) Patent Application Publication
(10) Pub. No.: US 2005/0250345 A1
(43) Pub. Date: Nov. 10, 2005

(54) METHOD FOR FABRICATING A BOTTLE-SHAPED DEEP TRENCH

(76) Inventors: Chien-Jung Sun, Taipei Hsien (TW); Chang-Rong Wu, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 10/709,444

(22) Filed: May 6, 2004

(51) Int. Cl. H01L 21/8242; H01L 21/76; H01L 21/302; H01L 21/461; H01L 21/31; H01L 21/469

(52) U.S. Cl. 438/778; 438/787; 438/791; 438/753

(57) ABSTRACT

A method for fabricating a bottle-shaped deep trench. The method comprises providing a substrate having a pad layer thereon, etching the pad layer and the substrate to form a deep trench in the substrate, performing an ALD process to form a nonmetal layer on the pad layer and on an upper portion of the sidewall of the deep trench, and performing an isotropic etching process to the sidewall and the bottom surface of the deep trench by taking the nonmetal layer as a hard mask so as to form a bottle-shaped deep trench.

### BACKGROUND OF INVENTION

1. Field of the Invention

The invention relates to a semiconductor fabrication process, and more particularly, to a semiconductor fabrication process which fabricates bottle-shaped deep trenches in a substrate.

2. Description of the Prior Art

Along with the development of miniaturization of various electrical products, DRAM elements have been pushed for size reductions to match the trend of high integration and high density. For increasing the integration, DRAMs with trench capacitor structures have become one of the main structures of high-integrated DRAM products used in industry. The theory of fabricating trench capacitors comprises forming a plurality of deep trenches in a substrate and forming capacitors in the deep trenches so as to reduce the area of each memory cell. However, as the line width of fabricating processes is reduced to 0.11 micrometers, the area of a trench capacitor is reduced, which directly affects the capacitance. When there is a shortage of capacitance, the information of charges stored in the capacitor is not easily detected, which results in making the capacitance difficult to ascertain. Therefore, increasing the capacitance is an urgent matter of the moment.

The capacitance has the calculation formula of:

$$C = k \times \frac{A}{d}$$

In the above formula, “C” represents capacitance; “A” represents the area of electrode plate or the capacitor area; “d” represents the thickness of the medium; and “k” represents the product of the intensity and constant of the medium. Accordingly, the area of the trench capacitor is one of the key factors affects the capacitance. Therefore, on the condition of fabricating DRAMs with small line widths, manufacturers have to form trench capacitors with greater areas in order to raise the capacitance. Consequently, manufacturers have designed a deep trench with wider space to make the deep trench look like a bottle with a collar and a bottle body, which is called a bottle-shaped deep trench, so that the trench capacitor may have a greater conduction area in the bottle body and the capacitance can be increased.

Please refer to FIGS. 1-4. FIGS. 1-4 are schematic diagrams of a method for fabricating a bottle-shaped deep trench in a substrate 10 according to the prior art. As shown in FIG. 1, the substrate 10 contains a deep trench 12. An oxide layer 14, a barrier layer 16, an amorphous layer 18, and a nitride layer 20 are first formed on the substrate 10 and the surface of the deep trench 12. Then, a photoresist layer 22 is formed on the substrate 10 and a recess etching (RE) process is performed to remove a portion of the photoresist layer 22 to expose a portion of the nitride layer 20 on the top of the deep trench 12. As shown in FIG. 2, an etching process is performed by taking the photoresist layer 22 as an etching mask to remove the exposed nitride layer 20 in order to expose a portion of the amorphous layer 22. After that, the residual photoresist layer 22 is removed and an oxidization process is performed to oxidize the exposed amorphous layer 22 for forming the silicon oxide layer 24.

Please refer to FIG. 3. The residual nitride layer 20 and amorphous layer 18 on the surface of the deep trench 12 are removed. Then, as shown in FIG. 4, the barrier layer 16 and the oxide layer 14 which are exposed after removing the amorphous layer 18 are removed to expose the bottom of the sidewall of the deep trench 12. Finally, the exposed substrate 10 is etched by taking the silicon nitride layer 24 as an etching mask to form the bottle-shaped deep trench 26.

Although bottle-shaped deep trenches can be formed to increase the areas of the trench capacitors according to the above-mentioned prior art method, the fabrication method is too complicated, which takes many heating processes, wet etching processes, and photolithography processes in various reaction chambers. Furthermore, the prior art method has a problem of metal contamination resulting from the fabrication processes. In this situation, the prior art method for fabricating bottle-shaped deep trenches requires a long process time and a high production cost, which cannot match the requirement of high efficiency and low production cost of DRAM manufacturers.

### SUMMARY OF INVENTION

It is therefore a primary objective of the claimed invention to provide a method for fabricating bottle-shaped deep trenches through simple processes to solve the prior art problem of the small capacitances of trench capacitors.

According to the claimed invention, the method of fabricating a bottle-shaped deep trench comprises providing a substrate having a pad layer thereon, etching the pad layer and the substrate to form a deep trench that has a sidewall and a bottom surface, performing an atomic layer deposition (ALD) process to form a nonmetal layer on the surface of the pad layer, which extends on an upper portion of the sidewall of the deep trench, and performing an isotropic etching process by taking the nonmetal layer as an etching mask to remove the sidewall and the bottom surface of the deep trench not covered by the nonmetal layer so as to form a bottle-shaped deep trench.

It is an advantage of the claimed invention that an ALD process is used to form a non-conformal nonmetal layer on the sidewall of the deep trench so that the nonmetal layer can be taken as an etching mask to etch the substrate for forming the bottle-shaped deep trench. Therefore, the fabrication process is simpler and the problem of metal contamination can be avoided. Accordingly, the production cost of DRAM can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIGS. 1-4 are schematic diagrams of a method for fabricating a bottle-shaped deep trench in a substrate according to the prior art.

FIGS. 5-8 are schematic diagrams of a method for fabricating a bottle-shaped deep trench in a substrate according to the present invention.

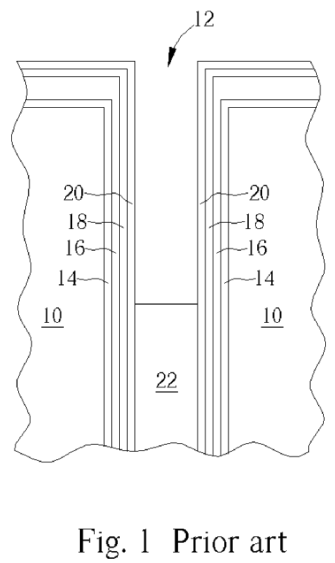

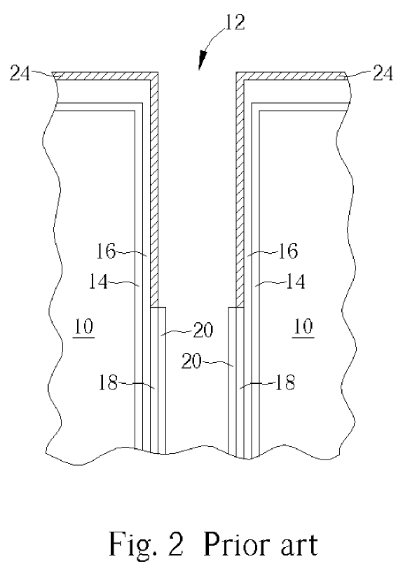

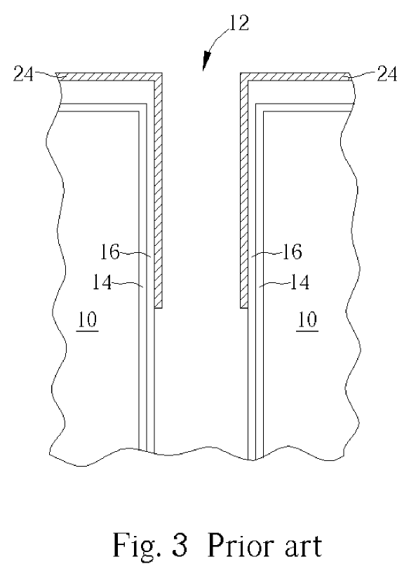

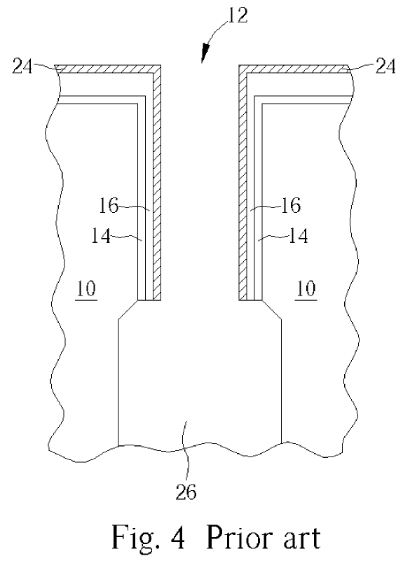

### DETAILED DESCRIPTION

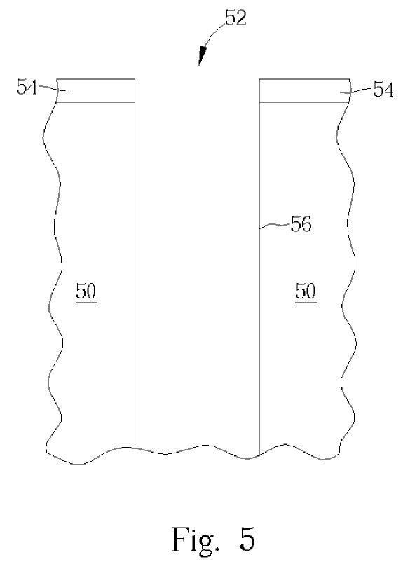

Please refer to FIGS. 5-8. FIGS. 5-8 are schematic diagrams of a method for fabricating a bottle-shaped deep trench according to the present invention. As shown in FIG. 5, the substrate 50 comprises a pad layer 54 thereon. At first, a photo-etching process (PEP) is performed to form a patterned photoresist layer (not shown) on the substrate 50. Then, the patterned photoresist layer is taken as an etching mask to etch the substrate 50 and the pad layer 54 to form at least a deep trench 52 that comprises a sidewall 56 and a bottom (not shown).

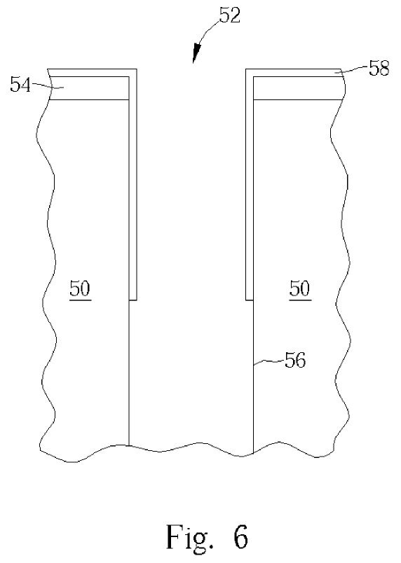

Referring to FIG. 6, an ALD process is performed to form a nonmetal layer 58 on the surface of the substrate 50 and to make the nonmetal layer 58 extend on the upper portion of the sidewall 56 of the deep trench 52. In this embodiment, the nonmetal layer 58 comprises silicon nitride (SiₓN_{y}, such as Si₃N₄) or silicon oxide. Taking the non-metal layer 58 formed of silicon nitride as an example, the fabricating process employs a first reactive gas containing silicon atoms or nitrogen atoms as a precursor to flow into the reaction chamber. Then, a second reactive gas is introduced into the reaction chamber, wherein the second reactive gas is a nitrogen-containing gas when the precursor is a silicon-containing gas, or the second reactive gas is a silicon-containing gas when the precursor is a nitrogen-containing gas. After the second reactive gas is introduced into the reaction chamber, the two reactive gases react with each other to form an extreme thin ALD silicon nitride layer, which is the nonmetal layer 58. In order to keep the nonmetal layer 58 on the upper portion of the sidewall 56 of the deep trench 52 without extending to the lower portion of the sidewall 56, as shown in FIG. 6, the reaction time and flow rates of the reactive gases have to be accurately controlled when introducing the reactive gases into the reaction chamber by pulses. Furthermore, when the desired shape of the nonmetal layer 58 is formed, the reactive gases have to be purged immediately. The ALD process may also be performed by introducing the first reactive gas and a gas containing ligends or catalysts into the reaction chamber simultaneously, and then introducing the second reactive gas into the reaction chamber after the first reactive gas is purged for forming the nonmetal layer 58.

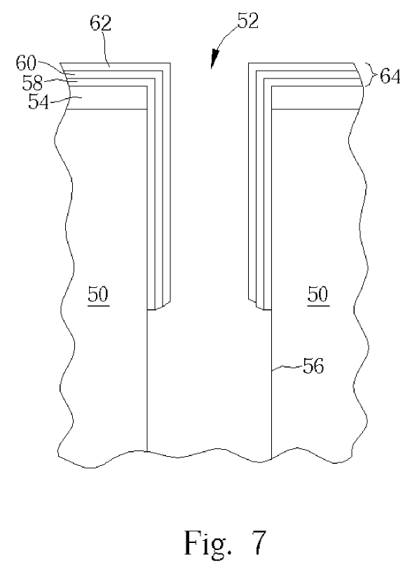

The thickness of the nonmetal layer 58 is about 80-100 angstroms (Å). Since the nonmetal layer 58 is very thin, the ALD process can be repeated several times to form a plurality of ALD layers on the substrate 50 and on the sidewall 56 of the deep trench 52, such as the nonmetal layers 58, 60, 62 shown in FIG. 7. Therefore the composite nonmetal layer 64 comprising the nonmetal layers 58, 60, 62 has a function of protecting the substrate 50. It should be noted that the amount of the ALD layers is not limited to the three nonmetal layers 58, 60, 62 shown in this embodiment provided that the composite nonmetal layer 64 can serve as an etching mask during substrate-etching process. On the other hand, the ALD process is preferably performed in a low-pressure chemical vapor deposition (LPCVD) chamber to form a preferable shape. In addition, in another embodiment of the present invention, the non-metal layers 58, 60, 62 can be formed of a silicon oxide layer.

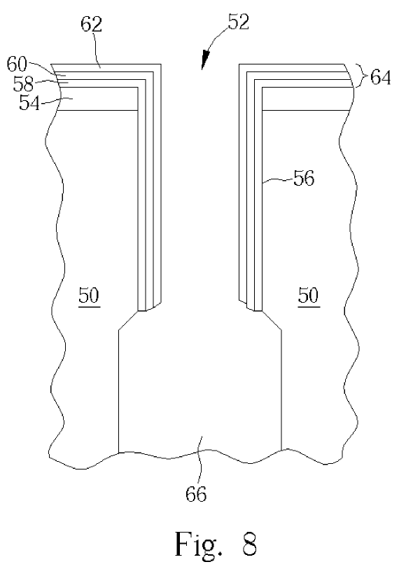

Then, as shown in FIG. 8, an isotropic etching process is performed by taking the composite nonmetal layer 64 as an etching mask to etch the substrate 50 and remove a portion of the sidewall 56 and the bottom of the deep trench 52 not covered by the composite nonmetal layer 64 so as to form a bottle-shaped deep trench 66. The isotropic etching process is capable of being a wet-etching process, which may selectively employ ammonia water (NH₄OH) as an etching agent for effectively removing the exposed sidewall 56. Finally, the composite non-metal layer 64 is removed and the fabrication of the trench capacitor or other elements can be performed continuously.

In contrast to the prior art, the present invention employs an ALD process to form a non-conformal nonmetal layer on the sidewall of the deep trench directly so that the nonmetal layer can serve as an etching mask during the isotropic etching process of the substrate for forming the bottle-shaped deep trench. According to the present invention, the complicated fabrication process of the prior art can be substantially simplified. In addition, since the flow rate of the nonmetal layer (ALD layer) formed by the ALD process is slower than that of the mask layer formed by a conventional deposition process, the nonmetal layer flowing in the deep trench can be kept to only stay on the upper portion of the sidewall of the deep trench by controlling the factors of pressure, pulse, and purge so that the nonmetal layer can have a desired shape to protect the upper sidewall of the deep trench and to expose the lower portion of the sidewall and bottom of the deep trench for forming a trench capacitor, instead of the complicated process to form the desired shape of the mask layer in the prior art. As a result, deep trenches and trench capacitors fabricated according to the present invention on a substrate do not have the problem of metal contamination and can save the production time and cost through a simply fabrication process.

Those skilled in the art will readily observe that numerous modifications and alterations of the device may be made while retaining the teachings of the invention. Accordingly, the above disclosure should be construed as limited only by the metes and bounds of the appended claims.

1. A method for fabricating a bottle-shaped deep trench comprising:
providing a substrate having a pad layer thereon;
etching the pad layer and the substrate to form a deep trench, the deep trench having a sidewall and a bottom surface;
performing an atomic layer deposition (ALD) process to form a nonmetal layer on the pad layer and on an upper portion of the sidewall of the deep trench, the nonmetal layer formed on the sidewall of the deep trench directly contacting the upper portion of the sidewall of the deep trench; and
performing an isotropic etching process by taking the nonmetal layer as a hard mask to remove a portion of the sidewall and the bottom surface of the deep trench not covered by the nonmetal layer so as to form a bottle-shaped deep trench.

2. The method of claim 1, wherein the ALD process is performed in a low-pressure chemical vapor deposition (LPCVD) chamber.

3. The method of claim 1, wherein the nonmetal layer is formed with a plurality of ALD processes.

4. The method of claim 1, wherein the nonmetal layer is an ALD nitride layer or an ALD oxide layer.

5. The method of claim 1, wherein the isotropic etching process is a wet-etching process.

6. The method of claim 5, wherein a wet-etching agent of the wet etching process is ammonia water (NH₄OH).

7. The method of claim 1, wherein the method further comprises a step of removing the nonmetal layer after forming the bottle-shaped deep trench.

8. (canceled)
